(19) United States
(12) Patent Application Publication
(10) Pub. No.: US 2026/0082739 A1
(43) Pub. Date: Mar. 19, 2026

(54) LIGHT-EMITTING DEVICE

(71) Applicant: Bridgelux Optoelectronics (Xiamen) Co., Ltd., Xiamen (CN)

(72) Inventors: JING CHEN, Xiamen (CN); BENJIE FAN, Xiamen (CN); HUNG-CHIH YANG, Xiamen (CN); DEBING HUANG, Xiamen (CN); YUEQIANG QIU, Xiamen (CN)

(21) Appl. No.: 19/026,702

(22) Filed: Jan. 17, 2025

(30) Foreign Application Priority Data
Sep. 14, 2024 (CN) 202411295470.5

(51) Int. Cl. H10H 20/851; H10H 20/854; H10H 29/24

(52) U.S. Cl. CPC H10H 20/8513; H10H 20/854; H10H 29/24

(57) ABSTRACT

A light-emitting device includes a broadband chip and an encapsulant. A full width at half maximum (FWHM) of the broadband chip is greater than or equal to 20 nanometers. The encapsulant is coated on the broadband chip. The encapsulant includes red fluoride phosphor. According to the light-emitting device, the encapsulant layer with red fluoride phosphor is excited by using the broadband chip with the FWHM greater than or equal to 20 nanometers, so that the light-emitting device can emit white light with high light efficiency and low color shift value, thereby solving the problem of serious color shift caused by red fluoride phosphor.

### TECHNICAL FIELD

The disclosure relates to the field of light-emitting diode (LED) lighting technologies, and more particularly to a light-emitting device.

### BACKGROUND

In the related art, phosphor is usually excited by a blue chip to emit white light, and the phosphor is mostly a combination of yellow-green phosphor and red phosphor. To achieve higher luminous efficiency, it is often necessary to use red fluoride phosphors. Compared with the commonly used red nitride phosphors, the red fluoride phosphors have the advantages of a narrower full width at half maximum (FWHM), higher excitation efficiency and lower absorption of light emitted by yellow-green phosphors. However, when the red fluoride phosphors applied to products with high color rendering indexes, a color shift is particularly noticeable. This leads to the need for targeted preparation of various products for minor differences in customer usage environments (such as operating temperature), resulting in a significant increase in production costs.

### SUMMARY

In view of at least some problems and deficiencies in the related art, the embodiment of the disclosure discloses a light-emitting device, so as to solve the problem of serious color shift of light-emitting products encapsulated by red fluoride phosphor in the related art.

In an aspect, a light-emitting device provided by an embodiment of the disclosure includes, for example, a broadband chip and an encapsulant that contain red fluoride phosphor. A full width at half maximum (FWHM) of the broadband chip is greater than or equal to 20 nanometers (nm). The encapsulant is coated on the broadband chip, and the encapsulant includes red fluoride phosphor.

The light-emitting device provided by the embodiment of the disclosure can emit white light with high luminous efficiency and low color shift by exciting the encapsulant layer with the red fluoride phosphor by using the broadband chip with the FWHM greater than or equal to 20 nanometers, thus solving the problem of serious color shift caused by red fluoride phosphor.

### BRIEF DESCRIPTION OF DRAWINGS

FIG. 1 illustrates a schematic structural diagram of a light-emitting device according to an embodiment of the disclosure.

FIG. 2 illustrates another schematic structural diagram of the light-emitting device according to the embodiment of the disclosure.

FIG. 3 illustrates a schematic diagram of luminescence spectrum of a broadband chip according to the embodiment of the disclosure at different operating temperatures.

FIG. 4 illustrates a schematic structural diagram of a chip on board (COB) encapsulated light-emitting device with multiple broadband chips.

FIG. 5 illustrates a chromaticity diagram of the light-emitting device and a LED package made of a traditional chip.

### DETAILED DESCRIPTION OF EMBODIMENTS

It should be noted that the terms “first” and “second” in the description and claims of the disclosure and the above drawings are used to distinguish similar objects, and are not necessarily used to describe a specific order or sequence. It should be understood that the terms so used are interchangeable under appropriate circumstances, so that the embodiments of the disclosure described herein can be implemented in other orders than those illustrated or described herein. Furthermore, the terms “including” and “having” and any variations thereof are intended to cover non-exclusive inclusion. In the specification, “on” means above or below the target component, and does not mean that it must be on top based on gravity.

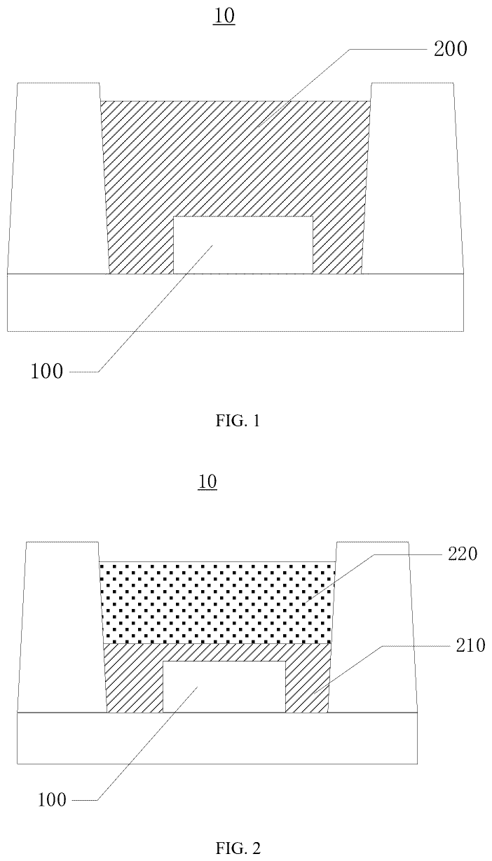

Referring to FIG. 1, a light-emitting device 10 provided by an embodiment of the disclosure includes, for example, a broadband chip 100 and an encapsulant 200. The broadband chip 100 is coated with the encapsulant 200, for example. Specifically, the broadband chip 100 is, for example, a light-emitting diode chip that can emit wide-band excitation light with a full width at half maximum (FWHM) of more than 20 nm by itself, such as a gallium nitride (GaN)-based broadband blue light chip. The encapsulant 200 includes red fluoride phosphor (such as KSF, KTF or KGF) in order to make the light-emitting device 10 have higher luminous efficiency. In order to make the light-emitting device 10 emit white light, the encapsulant 200 may also include other phosphors, such as yellow-green phosphors (such as LuAG, GaYAG, YAG, Silicate, β-SiAlON, etc.), and in order to obtain better color rendering index, the encapsulant 200 may further include red nitride phosphors (such as CASN, SCASN, etc.) or other phosphors.

Specifically, the broadband chip 100 adopted in the disclosure is a light-emitting diode different from the traditional narrowband chip, and it can have a light-emitting structure as described in Chinese patents CN201910318051.1, CN201980045780.2 or CN202010442369.3, including at least three quantum well layers with different indium concentrations, which are laminated and grown in a certain order, so that the manufactured broadband chip 100 can emit broadband blue light with only a single chip. Specifically, the luminescence spectrum of the broadband chip 100 may have an FWHM greater than 20 nanometers, and more specifically, the broadband chip 100 with an FWHM greater than 25 nanometers or greater than 30 nanometers may be selected in the disclosure.

The encapsulant 200 is obtained by mixing phosphor and silica gel. For example, all kinds of phosphor can be mixed together to form a single layer of encapsulant to cover the broadband chip 100. For example, as illustrated in FIG. 1, the red fluoride phosphor is mixed with yellow-green phosphor and other phosphor such as red nitride phosphor to make encapsulant, and the encapsulant 200 is coated on the broadband chip 100 to form a single layer of encapsulant, which is obtained by one-time dispensing, for example. Alternatively, multiple phosphors can be mixed with silica gel as required to make at least two kinds of encapsulant, which are layered and covered on the broadband chip. For example, as illustrated in FIG. 2, the red fluoride phosphor is separately made into a layer of encapsulant and set on the broadband chip 100 to form a first encapsulant layer 210, and yellow-green phosphor and other phosphor such as red nitride phosphor can be mixed to make another encapsulant and set on a side of the first encapsulant layer 210 facing away from the broadband chip 100 to form a second encapsulant layer 220. The first encapsulant layer 210 and the second encapsulant layer 220 are obtained by, for example, layering and dispensing.

The light-emitting device 10 provided by the embodiment of the disclosure can emit white light with high luminous efficiency and lower color shift value by exciting encapsulant with red fluoride phosphor by using a broadband chip with an FWHM greater than 20 nanometers. Specifically, referring to Table 1, Table 1 is the color coordinate change data of different light-emitting devices at 25° C. and 85° C. Among them, the control group is a white light-emitting device made of traditional narrowband chips (chips with FWHM less than 20 nanometers) and a single layer of encapsulant, and NO. 1-NO. 9 are white light-emitting devices made of different broadband chips and the single layer of encapsulant. Table 1 shows the changes of the measured color coordinates of these white light-emitting devices at different temperatures (such as 25° C. and 85° C.). From the data in Table 1, it can be seen that the use of broadband chip with red fluoride phosphor can reduce the color coordinate shift of the light-emitting devices, that is, color shift, compared with the traditional scheme of using the narrowband chip with red fluoride phosphor.

TABLE 1

| | Difference between X and y of | | Shift distance between |
|---|---|---|---|
| | coordinate point under 25° C.-85° C. | | two coordinate points |
| Number | Δx | Δy | under 25° C.-85° C. |
| Control | 0.0010 | −0.0092 | 0.00925 |
| group | | | |
| NO. 1 | −0.0017 | −0.0030 | 0.00343 |
| NO. 2 | −0.0008 | −0.0051 | 0.00518 |
| NO. 3 | −0.0008 | −0.0048 | 0.00490 |
| NO. 4 | 0.0000 | −0.0045 | 0.00448 |
| NO. 5 | −0.0038 | −0.0005 | 0.00383 |
| NO. 6 | −0.0023 | −0.0012 | 0.00261 |
| NO. 7 | −0.0012 | −0.0026 | 0.00284 |
| NO. 8 | −0.0008 | −0.0031 | 0.00325 |
| NO. 9 | −0.0021 | −0.0055 | 0.00590 |
| NO. 10 | 0.0052 | −0.0066 | 0.00842 |

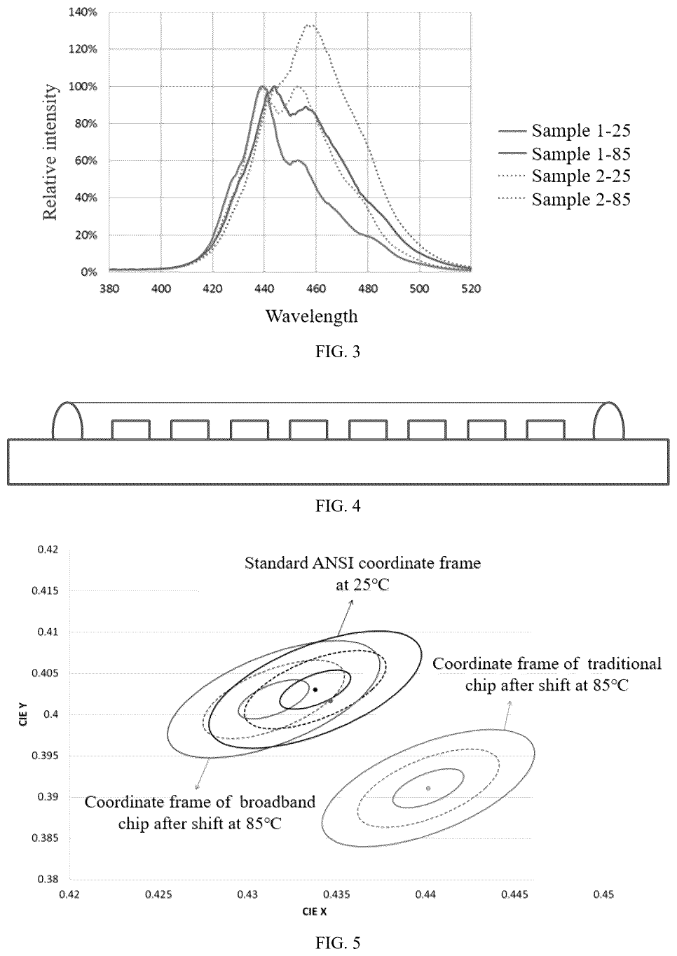

Further, a large number of test experiments have revealed that the broadband chip 100 with multiple peaks in the luminescence spectrum has a good effect of reducing color shift when used with the red fluoride phosphor. The broadband chip 100 selected in the disclosure has, for example, two or more peaks, specifically 2-5 peaks. FIG. 3 illustrates a schematic diagram of the luminescence spectrum of a kind of broadband chips with better color shift reduction effect at different operating temperatures. As shown in FIG. 3, the luminescence spectrums of this kind of broadband chips have at least one peak in the range of 432.5-450 nm. The first peak from 432.5 to 450 nanometers in this wavelength range is defined as the first peak turning point, and a peak adjacent to the first peak turning point on the long wavelength side is defined as the second peak turning point. In some embodiments, the wavelength value of the second peak turning point differs from the wavelength value of the first peak turning point by, for example, 8-20 nm. Specifically, the wavelength value of the second peak turning point may differ from the wavelength value of the first peak turning point by 10-14 nm. This kind of broadband chips can significantly reduce the large thermal color shift caused by the use of the red fluoride phosphor.

Furthermore, this kind of broadband chips are further screened and normalized by taking the spectral intensity of the first peak turning point as a reference, and it is found that the ratio of the spectral intensity of the second peak turning point to the first peak turning point at the operating temperature of 85° C. is higher than that at the operating temperature of 25° C., which could significantly reduce the thermal color shift when used with the red fluoride phosphor, and realize the color coordinate shift control as shown in FIG. 5. It can be clearly seen from FIG. 5 that compared with the scheme that the white light-emitting device 10 is made of traditional narrowband chips with the same phosphor, the broadband chip screened in this embodiment can significantly reduce the thermal color shift caused by the use of the red fluoride phosphor. For example, compared with the operating temperature of 25° C., the color coordinate shift distance can be less than 0.006 at the operating temperature of 85° C., and even less than 0.004 in some better schemes.

Taking sample 1 in FIG. 3 as an example, when the operating temperature is 25° C., the ratio of the spectral intensity of the second peak turning point to the first peak turning point is about 60%. When the operating temperature is 85° C., the spectrum fluctuates, and the ratio of the spectral intensity of the second peak turning point to the first peak turning point increases to 87%. Taking sample 2 as an example, when the operating temperature is 25° C., the ratio of spectral intensity between the second peak turning point to the first peak turning point is about 100%. When the operating temperature is 85° C., the spectrum fluctuates, and the ratio of the spectral intensity of the second peak turning point to the first peak turning point increases to 133%. In some embodiments, at the operating temperature of 25° C., the luminescence spectrum of the broadband chip 100, the ratio of the spectral intensity of the second peak turning point to the first peak turning point is, for example, between 50% and 100%, more specifically between 50% and 90%. When the operating temperature is 85° C., the ratio of the spectral intensity of the second peak turning point to the first peak turning point becomes larger, for example, between 60% and 150%. The screened broadband chip that meets the above conditions can further reduce the large thermal color shift caused by the use of the red fluoride phosphor.

From FIG. 3, it can also be seen that when the operating temperature rises, the luminescence spectrum of the broadband chip 100 will have a certain degree of red shift in addition to the waveform change. For the convenience of observation and screening, the above-mentioned broadband chip 100, which can reduce the thermal color shift of the red fluoride phosphor, usually has the following characteristics. The ratio of the spectral intensity at 460 nm to the spectral intensity at 440 nm is increased in the luminescence spectrum at an operating temperature of 85° C. as compared to the emission spectrum at an operating temperature of 25° C. The ratio of the spectral intensity at 460 nm to the spectral intensity at 440 nm at 85° C. of the broadband chip 100 is a first ratio, the ratio of the spectral intensity at 460 nm to the spectral intensity at 440 nm at 25° C. of the broadband chip 100 is a second ratio, and the first ratio is greater than second ratio. That is, the ratio of the spectral intensity at 460 nm to the spectral intensity at 440 nm of the broadband chip 100 at 85° C. is greater than ratio of the spectral intensity at 460 nm to the spectral intensity at 440 nm of the broadband chip 100 at 25° C.

Table 2 provides optical data of the light-emitting device 10 provided by this embodiment at different temperatures. In this embodiment, the light-emitting device 10 with a color temperature of 3000K is taken as an example. According to the data in Table 2, the color rendering index of the light-emitting device 10 provided in this embodiment can reach above 90 at 25° C.-105° C., for example, that is, it has a high color rendering index. In addition, as can be seen from Table 2, the color coordinate shift distance can be less than 0.006 at 25° C.-85° C. or even 25° C.-105° C.

TABLE 2

| | | | | Compared | | |
|---|---|---|---|---|---|---|
| | | | | with that | | |
| | | | | color | | |
| | | | | coordinate | | Color |
| Operating | luminous | | | shift distance | Color | rendering |
| temperature | flux/lm | CIE-X | CIE-Y | at 25° C. | temperature/K | index (CRI) |
| 25° C. | 1451.01 | 0.4383 | 0.4128 | / | 3047 | 91.6 |
| 55° C. | 1399.93 | 0.4371 | 0.4129 | 0.0012 | 3068 | 91.9 |
| 85° C. | 1312.18 | 0.4362 | 0.4112 | 0.0026 | 3070 | 93.2 |
| 105° C. | 1237.24 | 0.4358 | 0.4096 | 0.0041 | 3065 | 94.5 |

The package form of the light-emitting device 10 is, for example, COB package, surface mounted device (SMD) package, filament package, etc., which is not limited in this disclosure. However, it is particularly worth mentioning that for the COB package as shown in FIG. 4 or other light-emitting devices 10 with no package bracket and without a sufficient depth of operation space, by adopting the broadband chip of the disclosure, a variety of phosphors can be mixed and dispensed at one time, which saves working procedures, reduces the difficulty of the manufacturing process, and also can achieve a very good effect of reducing color shift. Referring to FIG. 5, taking the COB light-emitting device 10 with multiple broadband chips 100 as shown in FIG. 4 as an example, the distance between the center coordinate at 85° C. and the center coordinate at 25° C. is no more than 3 standard deviation of color matching (SDCM). Compared with COB light-emitting devices using conventional narrowband chips, the color shift problem has been significantly improved. Of course, for other light-emitting devices with better operation space, the layered dispensing process as shown in FIG. 2 can also be adopted to further reduce the color shift.

To sum up, the light-emitting device provided by the embodiment of the disclosure can emit white light with high color rendering index and low color shift by exciting the encapsulant layer with the red fluoride phosphor by using the broadband chip with an FWHM greater than or equal to 20 nm, thus solving the problem of serious color shift caused by the use of the red fluoride phosphor in high-efficiency light-emitting devices.

Finally, it should be noted that the above embodiments are only used to illustrate the technical solutions of the disclosure, but not to limit them. Although the disclosure has been described in detail with reference to the foregoing embodiments, those skilled in the art should understand that the technical solutions described in the foregoing embodiments can still be modified, or some of the technical features thereof can be equivalently replaced. However, these modifications or substitutions do not make the essence of the corresponding technical solutions deviate from the spirit and scope of the technical solutions of various embodiments of the disclosure.

What is claimed is:

1. A light-emitting device, comprising:
a broadband chip, wherein a full width at half maximum (FWHM) of the broadband chip is greater than or equal to 20 nanometers; and
an encapsulant, coated on the broadband chip, wherein the encapsulant comprises red fluoride phosphor.

2. The light-emitting device as claimed in claim 1, wherein a luminescence spectrum of the broadband chip has a plurality of peaks, the luminescence spectrum of the broadband chip has at least one peak in a range of 432.5 to 450 nanometers; a first peak from 432.5 to 450 nanometers is defined as a first peak turning point, and a peak adjacent to the first peak turning point on a long wavelength side is defined as a second peak turning point.

3. The light-emitting device as claimed in claim 2, wherein a wavelength value of the second peak turning point differs from that of the first peak turning point by 8 to 20 nanometers.

4. The light-emitting device as claimed in claim 2, wherein an intensity ratio of the second peak turning point to the first peak turning point at an operating temperature of 85° C. is greater than that at an operating temperature of 25° C.

5. The light-emitting device as claimed in claim 4, wherein the intensity ratio of the second peak turning point to the first peak turning point is in a range of 50%-100% at the operating temperature of 25° C.; and the intensity ratio of the second peak turning point to the first peak turning point is in a range of 60%-150% at the operating temperature of 85° C.

6. The light-emitting device as claimed in claim 1, wherein a color coordinate shift distance of light emitted by the light-emitting device at an operating temperature of 85° C. and light emitted by the light-emitting device at an operating temperature of 25° C. is not more than 0.006.

7. The light-emitting device as claimed in claim 1, wherein a ratio of a spectral intensity of the broadband chip at a wavelength of 460 nanometers to a spectral intensity at a wavelength of 440 nanometers at an operating temperature of 85° C. is a first ratio; and a ratio of the spectral intensity of the broadband chip at the wavelength of 460 nanometers to the spectral intensity at the wavelength of 440 nanometers at an operating temperature of 25° C. is a second ratio; and
wherein the first ratio is greater than the second ratio.

8. The light-emitting device as claimed in claim 1, wherein the broadband chip is multiple in number, and a distance between a color coordinate center of light emitted by the light-emitting device at an operating temperature of 85° C. and a color coordinate center of light emitted by the light-emitting device at an operating temperature of 25° C. does not exceed three standard deviation of color matching (SDCM).

9. The light-emitting device as claimed in claim 1, wherein the encapsulant further comprises at least one of yellow-green phosphor and red nitride phosphor, and the encapsulant is coated on the broadband chip to form a single encapsulant layer.

10. The light-emitting device as claimed in claim 1, wherein the encapsulant comprises a first encapsulant layer and a second encapsulant layer; the first encapsulant layer is arranged on the broadband chip, and the second encapsulant layer is arranged on a side of the first encapsulant layer facing away from the broadband chip; the first encapsulant layer comprises the red fluoride phosphor, and the second encapsulant layer comprises at least one of yellow-green phosphor and red nitride phosphor.

11. The light-emitting device as claimed in claim 1, wherein the FWHM of the broadband chip is greater than 25 nanometers.

12. A light-emitting device, comprising:
a broadband chip, wherein an FWHM of the broadband chip is greater than or equal to 20 nanometers; and
an encapsulant, coated on the broadband chip, wherein the encapsulant comprises red fluoride phosphor;
wherein a color rendering index (CRI) of the light-emitting device is greater than 90.

13. The light-emitting device as claimed in claim 12, wherein a color coordinate shift distance of light emitted by the light-emitting device at an operating temperature of 85° C. and light emitted by the light-emitting device at an operating temperature of 25° C. is not more than 0.006.

14. The light-emitting device as claimed in claim 12, wherein a ratio of a spectral intensity of the broadband chip at a wavelength of 460 nanometers to a spectral intensity at a wavelength of 440 nanometers at an operating temperature of 85° C. is a first ratio; and a ratio of the spectral intensity of the broadband chip at the wavelength of 460 nanometers to the spectral intensity at the wavelength of 440 nanometers at an operating temperature of 25° C. is a second ratio; and
wherein the first ratio is greater than the second ratio.

15. The light-emitting device as claimed in claim 12, wherein the encapsulant further comprises at least one of yellow-green phosphor and red nitride phosphor, and the encapsulant is coated on the broadband chip to form a single encapsulant layer.

16. A light-emitting device, comprising:
a broadband chip, wherein a luminescence spectrum of the broadband chip has a plurality of peaks; and
an encapsulant, coated on the broadband chip, wherein the encapsulant comprises red fluoride phosphor.

17. The light-emitting device as claimed in claim 16, the luminescence spectrum of the broadband chip has at least one peak in a range of 432.5 to 450 nanometers; a first peak from 432.5 to 450 nanometers is defined as a first peak turning point, and a peak adjacent to the first peak turning point on a long wavelength side is defined as a second peak turning point.

18. The light-emitting device as claimed in claim 17, wherein a wavelength value of the second peak turning point differs from that of the first peak turning point by 8 to 20 nanometers.

19. The light-emitting device as claimed in claim 16, wherein a ratio of a spectral intensity of the broadband chip at a wavelength of 460 nanometers to a spectral intensity at a wavelength of 440 nanometers at an operating temperature of 85° C. is a first ratio; and a ratio of the spectral intensity of the broadband chip at the wavelength of 460 nanometers to the spectral intensity at the wavelength of 440 nanometers at an operating temperature of 25° C. is a second ratio; and
wherein the first ratio is greater than the second ratio.

20. The light-emitting device as claimed in claim 16, wherein the encapsulant further comprises at least one of yellow-green phosphor and red nitride phosphor, and the encapsulant is coated on the broadband chip to form a single encapsulant layer.
